(19) United States
(12) Patent Application Publication
(10) Pub. No.: US 2019/0170915 A1
(43) Pub. Date: Jun. 6, 2019

(54) LIGHT SHIELDING MEMBER, METHOD FOR MANUFACTURING THE SAME AND CAMERA MODULE USING THE SAME

(71) Applicants: TRIPLE WIN TECHNOLOGY(SHENZHEN) CO.LTD., Shenzhen (CN); HON HAI PRECISION INDUSTRY CO., LTD., New Taipei (TW)

(72) Inventors: SHENG-JIE DING, Shenzhen (CN); JING-WEI LI, Shenzhen (CN); SHIN-WEN CHEN, Tu-Cheng (TW); KUN LI, Shenzhen (CN)

(21) Appl. No.: 15/869,190

(22) Filed: Jan. 12, 2018

(30) Foreign Application Priority Data
Dec. 5, 2017 (CN) 201711281549.2

(51) Int. Cl. G02B 5/00; G02B 7/02

(52) U.S. Cl. CPC G02B 5/003; G02B 7/02; H05K 1/09; H05K 2201/10121; H05K 2201/0364

(57) ABSTRACT

A light shielding member includes a transparent plate. The transparent plate includes a first surface and a second surface opposite to the first surface; the first surface of the transparent plate comprises a first light permeable area and a light shielding area surrounding the first light permeable area. The light shielding member further comprises a opaque adhesive layer formed on the light shielding area.

### FIELD

The subject matter herein generally relates to image capture, method for manufacturing light shield and camera module using the same.

### BACKGROUND

Generally, a lens module comprises a lens barrel, a shading plate arranged in the lens barrel. However, the light shading plate is formed by printing ink on a predetermined location of a large glass using screen printing, then the large glass is cut into a single plate, and then the single plate is assembled into the lens module. Because screen printing requires the development of molding, this process is time consuming.

### BRIEF DESCRIPTION OF THE DRAWINGS

Implementations of the present technology will now be described, by way of example only, with reference to the attached figures.

FIG. 1 is a schematic view of a camera module in one exemplary embodiment.

FIG. 2 is an exploded view of the camera module in FIG. 1.

FIG. 3 is a cross-sectional view of the camera module in FIG. 1.

FIG. 4 is a schematic view of a light shielding member in one exemplary embodiment.

FIG. 5 is a flowchart of a manufacturing method for a light shielding member.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to illustrate details and features of the present disclosure better. The disclosure is illustrated by way of example and not by way of limitation in the figures of the accompanying drawings, in which like references indicate similar elements. It should be noted that references to “an” or “one” embodiment in this disclosure are not necessarily to the same embodiment, and such references mean “at least one.”

Several definitions that apply throughout this disclosure will now be presented.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series, and the like. The references “a plurality of” and “a number of” mean “at least two.”

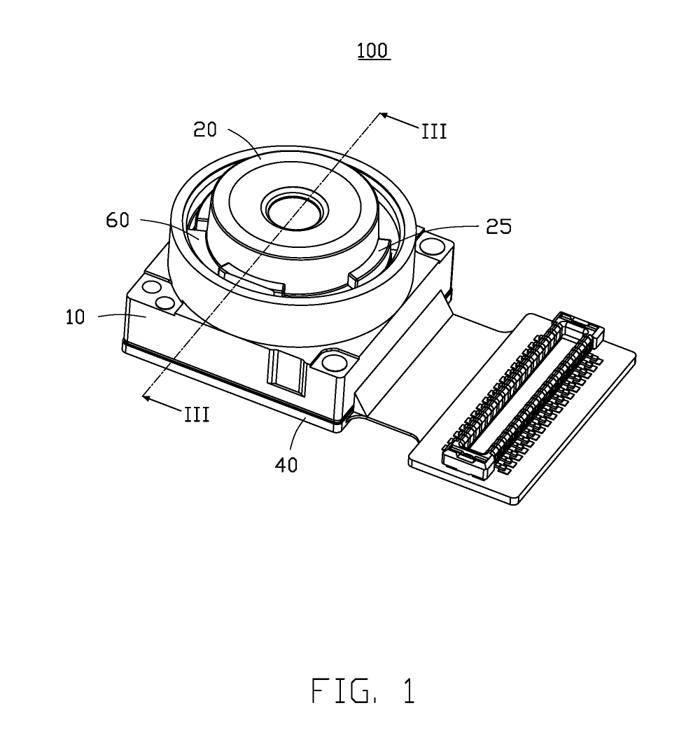

FIGS. 1˜3 illustrate a camera module 100 according to one embodiment. The camera module 100 includes a lens holder 10, a lens module 20, a light shielding member 30, a printed circuit board 40, and an imaging sensor chip 50 mounted on the printed circuit board 40.

The lens holder 10 is configured to receive lens module 20, the lens holder 10 can also be a voice coil motor. In the illustrate embodiment, the lens holder 10 comprises a base 12 and a first joint portion 14 protruding from the base 12. The first joint portion 14 is substantially a hollow cylinder and configured to receive the lens module 20. The lens module 20 includes at least one lens.

In the embodiment, the inner surface 103 of the first joint portion 14 includes a plurality of internal threads. The lens module 20 includes a second joint portion 21 matching the shape of the inner surface 103 of the first joint portion 14, the outer surface 203 of the second joint portion 21 includes a plurality of external threads, and the lens camera 20 can thus be screwed into the lens holder 10.

In other embodiments, the lens camera 20 and the lens holder 10 are not threaded combination or are integrally formed in a mold. That is to say, the external threads and the internal threads can be omitted.

The lower end of the inner surface 103 of the base 12 is arranged with a supporting flange 105 extending along a radial direction of the lens holder 10, and the light shielding member 30 is mounted on the supporting flange 105. The light shielding member 30 can be a round shape, a rectangle, or a polygon. In the illustrated embodiment, the light shielding member 30 has a rectangle shape.

The light shielding member 30 includes a transparent plate 31. The light shielding member 30 can be a round shape, a rectangle, or a polygon. The transparent plate 31 is made from glass or plastic. The transparent plate 31 includes a light permeable area 315 and a light shielding area 316 that surrounds the light permeable area 315. In the illustrated embodiment, the light permeable area 315 is a through hole passing through the transparent plate 31.

The light shielding area 316 is an opaque adhesive 318, in the present embodiment, the light shielding area 316 is a black adhesive formed on the light shielding area 316. The opaque adhesive 318 can be formed on one surface of the transparent plate 31 or two opposing surfaces of the transparent plate 31. In the illustrated embodiment, the opaque adhesive 318 is formed on one surface of the transparent plate 31. The light shielding member 30 is fixed on the supporting flange 105 via the opaque adhesive 318.

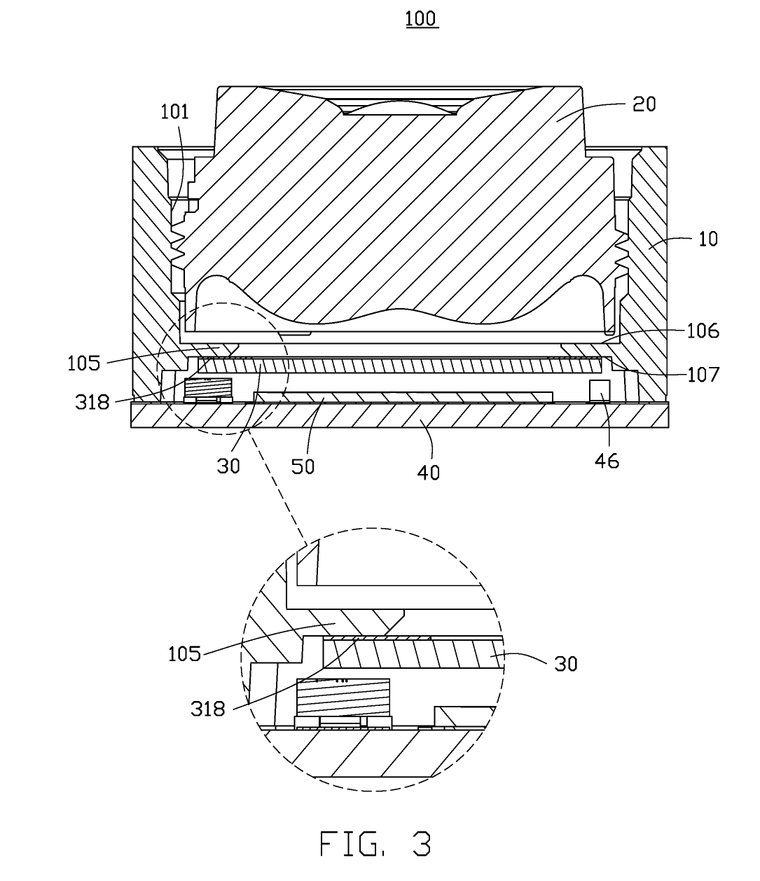

The supporting flange 105 includes a top surface 106 and a bottom surface 107 opposite to the top surface 106. The light shielding member 30 is mounted on the bottom surface 107 and part of the opaque adhesive 318 is exposed from the supporting flange 105, as shown in FIG. 3. The exposed portion of the opaque adhesive 318 adsorbs dust or other particles fallen on the light shielding member 30.

The printed circuit board 40 is a flexible printed circuit board, a rigid-flexible printed circuit board, or a ceramic substrate.

The imaging sensor chip 50 is electrically connected with the printed circuit board 40. The imaging sensor chip 50 includes a plurality of edge connectors 52 (gold fingers) arranged peripherally thereon. The printed circuit board 40 includes a plurality of pads 42, and the pads 42 are electrically connected with the gold fingers 52 via wires, such as gold wires. The printed circuit board 40 is also provided with a number of electronic components 46 to improve performance of the imaging sensor chip 50, for example, the electronic components 46 can be resistors and capacitors. The light shielding element 30 is configured to adsorb light rays reflecting off the wires, and glare is prevented, thus, improving the imaging quality of the lens module 100.

Rim of the second joint portion 21 further comprises a flange 23 thereon, and a number of adjustment bumps 25 are formed on the flange 23. The adjustment bumps 25 can be used in adjusting optical axis of the lens module 20.

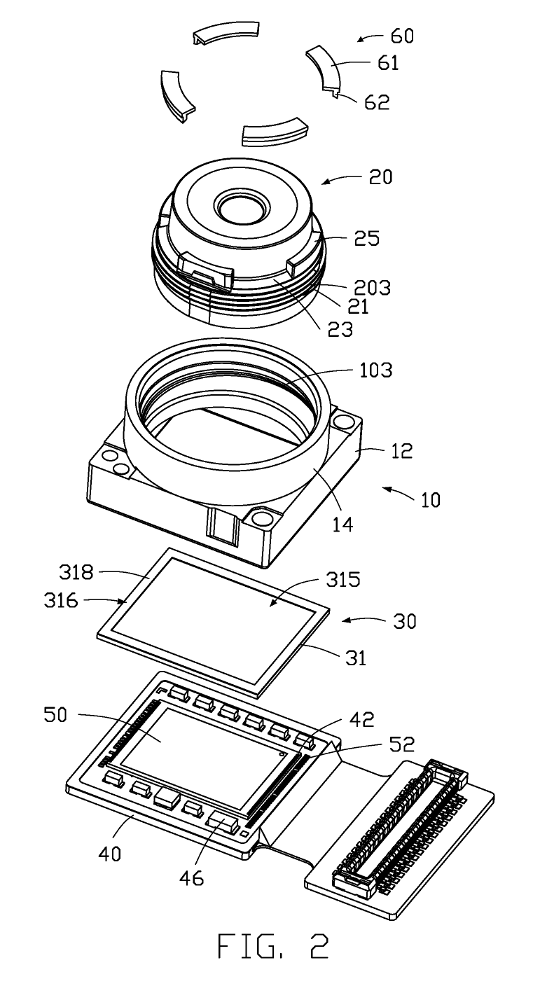

The camera module 100 further comprises a plurality of fixing members 60, as shown in FIG. 2, and each fixing member 60 is arranged between two adjacent adjustment bumps 25. The fixing member 60 is substantially L-shaped, and comprises a first portion 61 and a second portion 62 perpendicularly connected to the first portion 61. The first portion 61 is fixed on the flange 23, and the second portion 62 is inserted into the gap formed between the lens module 20 and the lens holder 10. The fixing member 60 is configured to fix the lens module 20 and the lens holder 10 and prevent dust fallen inside the lens holder 10.

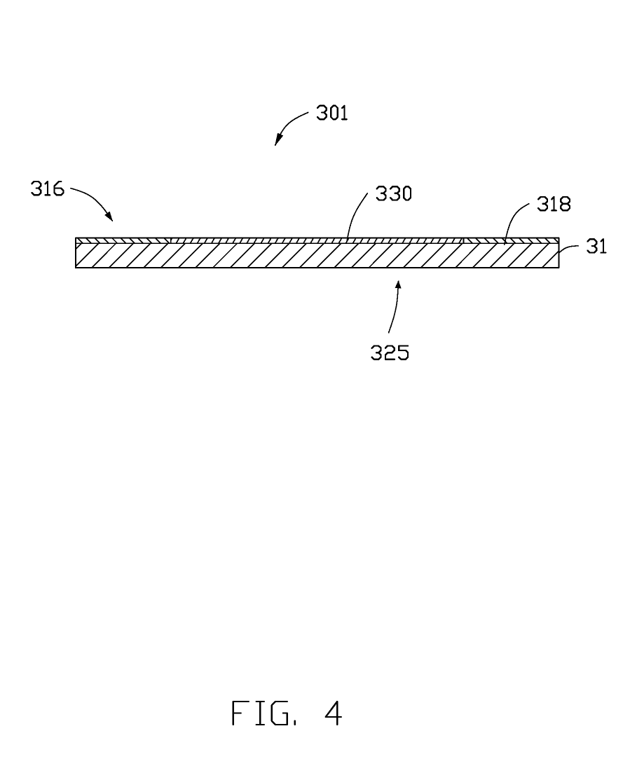

FIG. 4 illustrates a light shielding member 301 according to another embodiment. The light shielding member 301 in FIG. 4 is similar to the light shielding member 30 in FIGS. 2-3. The difference between the light shielding member 301 and the light shielding member 30 in FIGS. 2-3 is that the light permeable area 325 of the light shielding member 301 is part of the transparent plate 31 surrounded by the light shielding area 316.

The light permeable area 325 is formed with a functional filter film 330. The functional filter film 330 is one of an infrared light cut-off filter film, an ultraviolet cut-off filter film, a low pass filter film, and an antireflective film. The functional filter film 330 is able to be formed on two opposite surfaces of the light permeable area 325, or formed on only one surface on the light permeable area 325.

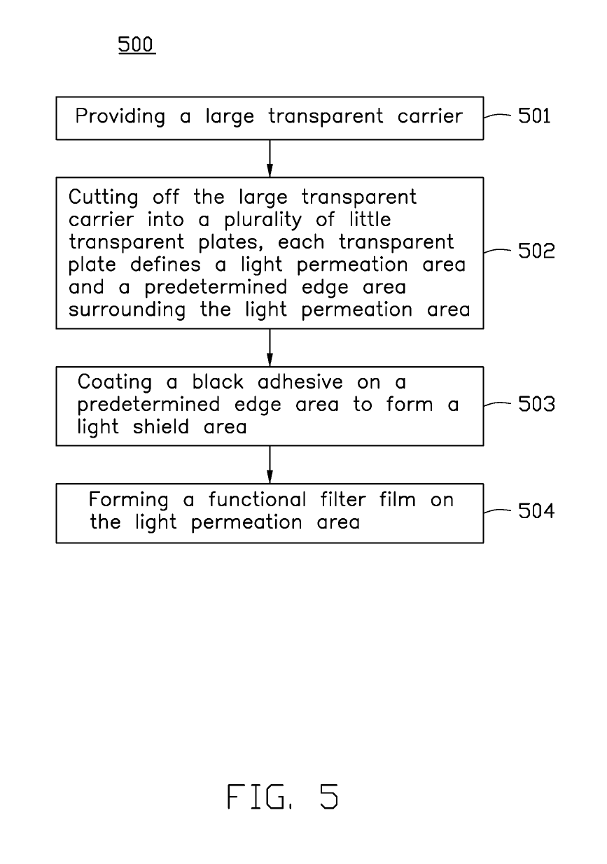

FIG. 5 illustrates a method for manufacturing light shielding member 301 according to one embodiment. The method is provided by way of example as there are a variety of ways to carry out the method. The method can begin at block 501.

At block 501, a large transparent carrier sheet is provided.

At block 502, the transparent carrier sheet is cut into a plurality of transparent plates, each transparent plate defines a light permeable area and a predetermined edge area surrounding the light permeable area.

At block 503, a opaque adhesive is coated on the predetermined edge area to form a light shielding area.

At block 504, a functional filter film 330 is formed on the light permeable area. The functional filter film is one of an infrared light cut-off filter film, an ultraviolet cut-off filter film, a low pass filter film, and an antireflective film.

The embodiments shown and described above are only examples. Therefore, many commonly-known features and details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will, therefore, be appreciated that the embodiments described above may be modified within the scope of the claims.

What is claimed is:

1. A light shielding member, comprising:
a transparent plate having a light permeable area and a light shielding area surrounding the light permeable area, wherein the light shielding area is a opaque adhesive formed on the transparent plate.

2. The light shielding member of claim 1, wherein the light permeable area is a through hole passing through the transparent plate.

3. The light shielding member of claim 1, wherein the light permeable area is a portion of the transparent plate surrounded by the light shielding area.

4. The light shielding member of claim 3, wherein the light permeable area is formed with a functional filter film.

5. The light shielding member of claim 4, wherein the functional filter film is at least one of an infrared light cut-off filter film, an ultraviolet cut-off filter film, a low pass filter film, and an antireflective film.

6. The light shielding member of claim 1, wherein the transparent plate is made from glass or plastic.

7. The light shielding member of claim 1, wherein the opaque adhesive is a black adhesive.

8. A method for manufacturing a light shielding member, comprising:
providing a large transparent carrier sheet;
cutting off the large transparent carrier sheet into a plurality of little transparent plates, each transparent plate defines a light permeable area and a predetermined edge area surrounding the light permeable area;
coating a opaque adhesive on a predetermined edge area to form a light shielding area.

9. The method for manufacturing a light shielding member of claim 8, wherein the light permeable area is a portion of the transparent plate surrounded by the light shielding area, and further comprises:
forming a functional filter film on the light permeable area.

10. The method for manufacturing a light shielding member of claim 9, wherein the functional filter film is at last one of an infrared light cut-off filter film, an ultraviolet cut-off filter film, a low pass filter film, and an antireflective film.

11. A camera module, comprising:
a lens holder, a lens module, a light shielding member, a printed circuit board and an imaging sensor chip mounted on the printed circuit board, the lens module and the light shielding member are received in the lens holder, the lens holder is mounted on the printed circuit board and surrounds the imaging sensor chip, and the light shielding member locates between the lens module and the imaging sensor chip, wherein the light shielding member comprising transparent plate, and the transparent plate comprising a light permeable area and a light shielding area surrounding the light permeable area, wherein the light shielding area is a opaque adhesive formed on the transparent plate.

12. The camera module of claim 11, wherein the light permeable area is a through hole passing through the transparent plate.

13. The camera module of claim 12, wherein the light permeable area is a portion of the transparent plate surrounding by the light shielding area.

14. The camera module of claim 11, wherein the light permeable area is a portion of the transparent plate surrounding by the light shielding area.

15. The camera module of claim 14, wherein the functional filter film is at least one of an infrared light cut-off filter film, an ultraviolet cut-off filter film, a low pass filter film, and an antireflective film.

16. The camera module of claim 11, wherein the transparent plate is made from glass or plastic.

17. The camera module of claim 11, wherein the lens holder comprises an inner surface, the lower end of the inner surface is arranged with a supporting flange extending along a radial direction of the lens holder, and the light shielding member is mounted on the supporting flange via the opaque adhesive layer, and the supporting flange exposes portions of the opaque adhesive layer.

18. The camera module of claim 11, wherein rim of the lens module comprises a flange thereon, and a plurality of adjustment bumps are formed on the flange.

19. The camera module of claim 18, wherein the camera module further comprises a number of fixing members, and each of the plurality of the fixing members are arranged between two adjacent adjustment bumps.
